(19) United States
(12) Patent Application Publication
(10) Pub. No.: US 2017/0150611 A1
(43) Pub. Date: May 25, 2017

(54) METHOD FOR SILKSCREEN PRINTING DURING MANUFACTURE OF PRINTED CIRCUIT BOARD

(71) Applicants: Fu Tai Hua Industry (Shenzhen) Co., Ltd., Shenzhen (CN); HON HAI PRECISION INDUSTRY CO., LTD., New Taipei (TW)

(72) Inventor: XUE-QIN ZHANG, Shenzhen (CN)

(21) Appl. No.: 15/075,454

(22) Filed: Mar. 21, 2016

(30) Foreign Application Priority Data
Nov. 20, 2015 (CN) 201510809287.7

(51) Int. Cl. H05K 3/12; H05K 1/09; H05K 1/02; H05K 3/00

(52) U.S. Cl. CPC H05K 3/1225; H05K 3/0047; H05K 1/092; H05K 1/0268

(57) ABSTRACT

A method for silkscreen printing during manufacture of a printed circuit board includes forming a circuit pattern on a trepanned circuit board using a first silkscreen plate that has the circuit pattern, the scraper, and conductive inks, forming a solder mask layer on the circuit board using a second silkscreen plate, the scraper, and a solder material, forming words and marks on the circuit board using a third silkscreen plate, the scraper, and inks, and forming a solder paste layer on the circuit board using a fourth silkscreen plate, the scraper, and solder paste.

### CROSS-REFERENCE TO RELATED APPLICATIONS

This application claims priority to Chinese Patent Application No. 201510809287.7 filed on Nov. 20, 2015, the contents of which are incorporated by reference herein.

### FIELD

The subject matter herein generally relates to printed circuit board manufacture, and particularly to a method for silkscreen printing during manufacture of a printed circuit board.

### BACKGROUND

In a traditional process of manufacturing printed circuit board, steps of copper deposition, circuit diagram transfer, circuit diagram electroplating, film stripping, etching, tin stripping, solder resist pattern transfer, and tin deposition are usually included.

### BRIEF DESCRIPTION OF THE DRAWINGS

FIG. 1 illustrates a flowchart of a method for silkscreen printing during manufacture of a printed circuit board of one embodiment.

FIGS. 2-3 illustrate a flowchart of a method for silkscreen printing during manufacture of a multilayer printed circuit board of one embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts can be exaggerated to better illustrate details and features. The description is not to be considered as limiting the scope of the embodiments described herein.

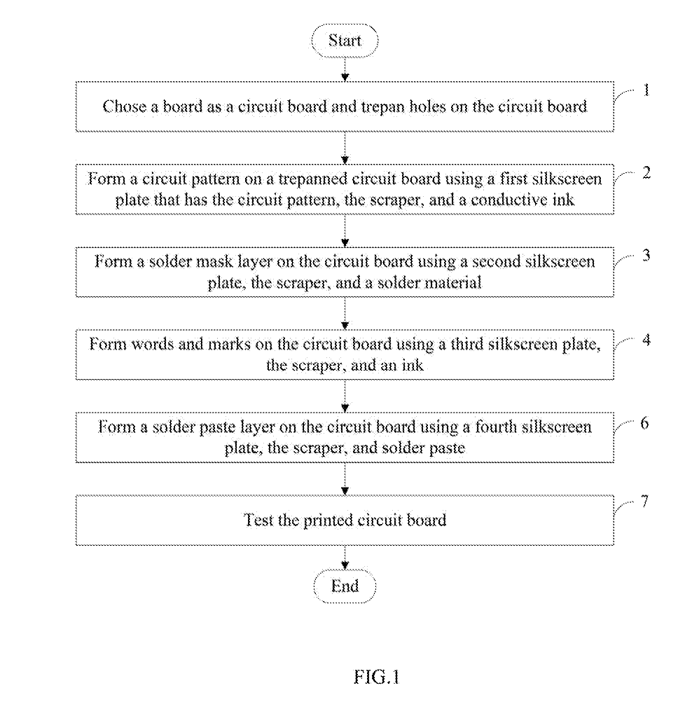

FIG. 1 illustrates a flowchart of a method for silkscreen printing during manufacture of a printed circuit board. In the illustrated embodiment, the circuit board is printed by use of a number of silkscreen plates, a scraper, printing materials, and other steps.

In the illustrated embodiment, the silkscreen plate is presented as a net structure plate. The silkscreen plate includes a template, a silkscreen, and a frame. The template is pasted on the silkscreen, and the silkscreen is fixed on the frame. In the illustrated embodiment, the scraper is made from rubber material, and is used for scraping some printing materials on the silkscreen plate.

The silkscreen plate includes a first area, a second area, and a number of meshes, wherein at least one pattern is printed on the first area. The printing materials can pass through the meshes on the first area, but cannot pass through the meshes on the second area. Thus, the scraper can scrape the printing materials onto a printing surface of an object to be printed through the first area of the silkscreen plate.

In the illustrated embodiment, the pattern on the first area of the silkscreen plate can be a circuit diagram of a circuit board or can correspond to a printing area of the circuit board. The scraper scrapes the printing materials on the silkscreen plate to the circuit board through the silkscreen plate.

As illustrated in FIG. 1, the method is provided by way of example, as there are a variety of ways to carry out the method. Each block shown in FIG. 1 represents one or more processes, methods, or subroutines carried out in the example method. Furthermore, the illustrated order of blocks is by example only and the order of the blocks can be changed.

Additional blocks may be added or fewer blocks may be utilized, without departing from this disclosure. The example method can begin at block 1.

At block 1, a board is chosen as a circuit board and holes are trepanned on the circuit board.

At block 2, a circuit diagram is formed on the trepanned circuit board using a first silkscreen plate, the scraper, and conductive inks.

In the illustrated embodiment, the circuit diagram is printed on the first area of the first silkscreen plate. The first silkscreen plate is fixed on the trepanned circuit board, wherein the circuit diagram on the first silkscreen plate is aligned to an area where a circuit diagram is to be formed on the circuit board. The conductive inks are put on one end of the first silkscreen plate. The scraper moves the conductive inks around between the end having the conductive inks and the other end, thus the conductive inks are extruded to the circuit board from the meshes on the first area of the first silkscreen plate by the scraper. The circuit diagram is thereby formed on the circuit board.

In the illustrated embodiment, the scraper moves around repeatedly to distribute the conductive inks uniformly on the circuit diagram area of the circuit board. When the circuit diagram is formed on the circuit board, the scraper is cleaned prior to being reused. In the illustrated embodiment, the conductive inks are a type of pasty inks with conductive materials, such as gold, silver, copper, or carbon.

At block 3, a solder mask layer is formed on the circuit board using a second silkscreen plate, the scraper, and solder materials.

In the illustrated embodiment, a pattern corresponding to the solder mask layer is printed on the first area of the second silkscreen plate. The second silkscreen plate is fixed on the circuit board, wherein the pattern on the second silkscreen plate is aligned to an area where the solder mask layer is to be formed on the circuit board. The solder materials are put on one end of the silkscreen plate. The scraper moves the solder materials around between the end having the solder materials and the other end, thus the solder materials are extruded to the circuit board from the meshes on the first area of the second silkscreen plate by the scraper. The solder mask layer is thereby formed on the circuit board.

When the solder mask layer is formed on the circuit board, the scraper is cleaned prior to being reused. In the illustrated embodiment, the solder materials can be green solder resists, blue solder resists, or red solder resists.

At block 4, words and marks are formed on the circuit board using a third silkscreen plate, the scraper, and inks.

In the illustrated embodiment, the words and marks are printed on the first area of the third silkscreen plate. The third silkscreen plate is fixed on the circuit board, wherein the words and marks on the third silkscreen are aligned to an area or areas on which the words and marks are to be formed on the circuit board. The inks are put on one end of the third silkscreen plate. The scraper moves the inks around between the end having the inks and the other end, thus the inks are extruded onto the circuit board from the meshes on the first area of the third silkscreen plate by the scraper. The words and marks are thereby formed on the circuit board.

When the words and marks are formed on the circuit board, is cleaned prior to being reused. In the illustrated embodiment, the inks are thermosetting inks.

At block 5, a solder paste layer is formed on the circuit board using a fourth silkscreen plate, the scraper, and solder paste.

In the illustrated embodiment, a pattern corresponding to the solder paste layer is printed on the first area of the fourth silkscreen plate. The fourth silkscreen plate is fixed on the circuit board, wherein the pattern on the fourth silkscreen plate is aligned to an area where the solder paste layer to be formed on the circuit board. The solder paste is put on one end of the fourth silkscreen plate. The scraper moves the solder paste around between the end having the solder paste and another end, thus the solder paste are extruded to the circuit board from the meshes on the first area of the fourth silkscreen plate by the scraper. The solder paste layer is thereby formed on the circuit board. When the solder paste layer is formed on the circuit board, the scraper is cleaned prior to being reused.

At block 6, the printed circuit board is tested.

In the illustrated embodiment, the printed circuit board test includes electrical test and visual inspection. The electrical test checks whether an open circuit or a short circuit exists, and the visual inspection checks the appearance of the printed circuit board.

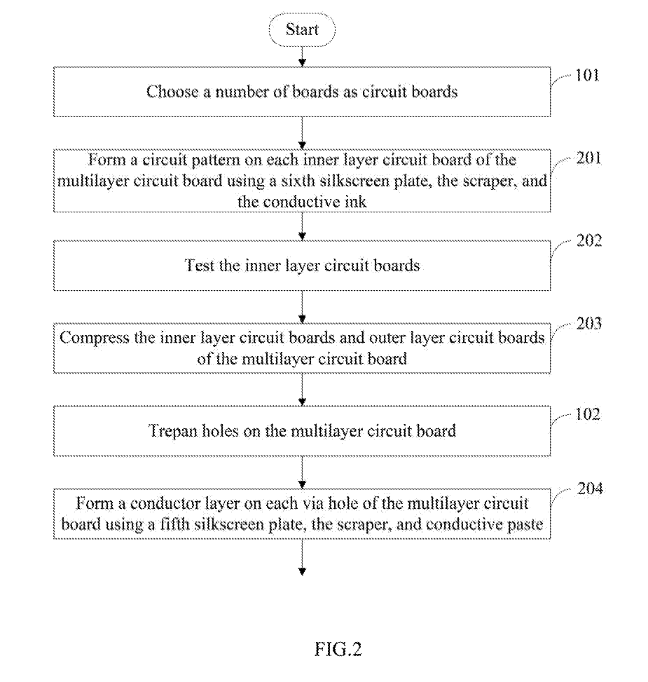

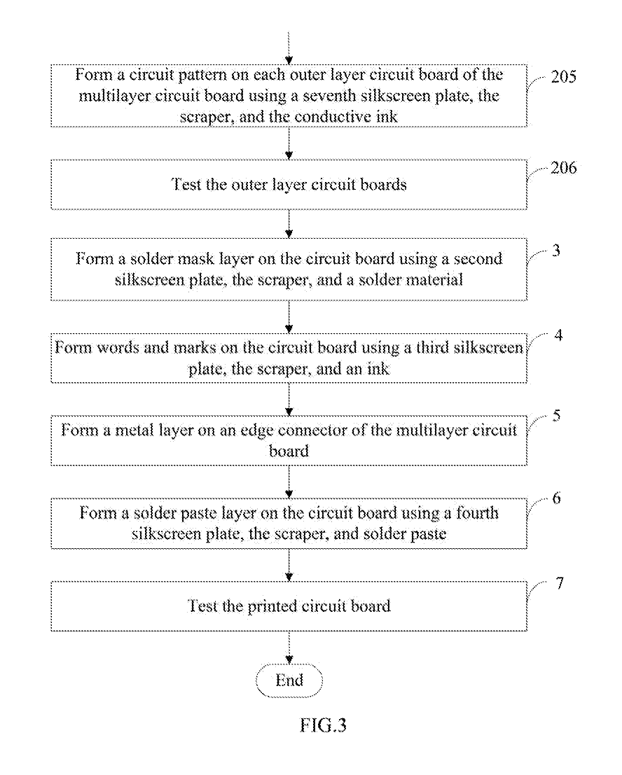

FIG. 2 and FIG. 3 illustrate a flowchart of a method for silkscreen printing during manufacture of a multilayer printed circuit board. The method is provided by way of example, as there are a variety of ways to carry out the method. Each block shown in FIG. 2 and FIG. 3 represents one or more processes, methods, or subroutines carried out in the example method. Furthermore, the illustrated order of blocks is by example only and the order of the blocks can be changed. Additional blocks may be added or fewer blocks may be utilized, without departing from this disclosure.

At block 101, a number of boards are chosen as circuit boards.

At block 102, a circuit diagram is formed on each inner layer of the multilayer circuit board using a sixth silkscreen plate, the scraper, and the conductive inks. In the illustrated embodiment, the circuit diagram is printed on the first area of the sixth silkscreen plate.

At block 103, when the circuit diagram is formed on each inner layer circuit board, the inner layer circuit boards are tested.

At block 104, the inner layer circuit boards and the outer layer circuit boards of the multilayer circuit board are compressed.

At block 105, holes are trepanned on the multilayer circuit board. In the illustrated embodiment, the trepanned holes include location holes and via holes.

At block 106, a conductor layer is formed on each via hole of the multilayer circuit board using a fifth silkscreen plate, the scraper, and conductive paste.

In the illustrated embodiment, a pattern corresponding to the via holes is printed on the first area of the fifth silkscreen plate. The fifth silkscreen plate is fixed on the circuit board, wherein the pattern on the fifth silkscreen plate is aligned to the via holes to be formed the conductor layer on the circuit board. The conductive paste is put on one end of the fifth silkscreen plate. The scraper moves the conductive paste around between the end having the conductive paste and the other end, thus the conductive paste is extruded to the via holes of the circuit board from the meshes on the first area of the fifth silkscreen plate by the scraper. The conductor layer is thereby formed in each via hole when the conductive paste solidifies.

When the conductor layer is formed in each via hole of the circuit board, the scraper is cleaned prior to being reused. In the illustrated embodiment, the conductive paste can be silver paste, copper paste, or carbon paste.

At block 107, a circuit diagram is formed on each outer layer circuit board of the multilayer circuit board using a seventh silkscreen plate, the scraper, and the conductive inks. In the illustrated embodiment, the circuit diagram is printed on the first area of the seventh silkscreen plate.

At block 108, when the circuit diagram is formed on each outer layer circuit board, the outer layer circuit boards are tested.

At block 109, a solder mask layer is formed on the multilayer circuit board using a second silkscreen plate, the scraper, and solder materials.

At block 110, words and marks are formed on the multilayer circuit board using a third silkscreen plate, the scraper, and inks.

At block 111, a metal layer is formed on an edge connector of the multilayer circuit board. In the illustrated embodiment, the metal layer is nickel and/or gold.

At block 112, a solder paste layer is formed on the multilayer circuit board using a fourth silkscreen plate, the scraper, and solder paste.

At block 113, the printed circuit board is tested.

In the process of manufacturing the printed circuit board using the silkscreen printing method, steps of copper deposition, circuit diagram transfer, circuit diagram electroplating, film stripping, etching, tin striping, solder resist pattern transfer, and tin deposition are avoided, thus less time is spent for manufacturing the printed circuit board. At the same time, less pollution is generated during manufacture of such printed circuit board.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

1. A method for silkscreen printing during manufacture of a printed circuit board, the method comprising:
forming a circuit pattern on a trepanned circuit board using a first silkscreen plate that has the circuit pattern, the scraper, and a conductive ink, wherein the circuit pattern on the first silkscreen plate is aligned to an area where a circuit pattern is to be formed on the printed circuit board, the conductive ink is put on one end of the first silkscreen plate, the scraper moves the conductive ink around repeatedly between the end having the conductive ink and the other end to distribute the conductive ink uniformly on the circuit pattern area of the circuit board;
forming a solder mask layer on the circuit board using a second silkscreen plate, the scraper, and a solder material;
forming words and marks on the circuit board using a third silkscreen plate, the scraper, and an ink; and
forming a solder paste layer on the circuit board using a fourth silkscreen plate, the scraper, and solder paste.

2. The method according to claim 1, further comprising:
testing the printed circuit board.

3. The method according to claim 2, wherein the printed circuit board is tested by electrical testing and visual inspection.

4. The method according to claim 1, wherein, the printed circuit board is a multilayer circuit board comprising a plurality of inner layer circuit boards and an outer layer circuit board, the method further comprises:
compressing the plurality of inner layer circuit boards and the outer layer circuit board of the multilayer circuit board;
trepanning holes on the multilayer circuit board; and
forming a conductor layer on each via hole of the multilayer circuit board using a fifth silkscreen plate, the scraper, and conductive paste.

5. The method according to claim 4, wherein the conductive paste is silver paste, copper paste, or carbon paste.

6. The method according to claim 4, further comprising:
testing each inner layer circuit board of the plurality of inner layer circuit boards; and
testing the outer layer circuit board.

7. The method according to claim 4, further comprising:
forming a metal layer on an edge connector of the multilayer circuit board.

8. The method according to claim 7, wherein the metal layer is nickel and/or gold.

9. The method according to claim 1, wherein the conductive ink is a type of pasty ink with a conductive material.

10. The method according to claim 1, wherein the solder material is green solder resists, blue solder resists, or red solder resists.

11. The method according to claim 1, wherein the ink is thermosetting ink.
